(19) United States
(12) Patent Application Publication
(10) Pub. No.: US 2011/0291171 A1
(43) Pub. Date: Dec. 1, 2011

(54) VARACTOR

(75) Inventors: John J. Pekarik, Underhill, VT (US); William F. Clark, JR., Essex Junction, VT (US); Robert J. Gauthier, JR., Hinesburg, VT (US); Yun Shi, South Burlington, VT (US); Yanli Zhang, San Jose, CA (US)

(73) Assignee: International Business Machines Corporation, Armonk, NY (US)

(21) Appl. No.: 13/050,043

(22) Filed: Mar. 17, 2011

(30) Foreign Application Priority Data
May 25, 2010 (EP) 10163781.7

(51) Int. Cl. H01L 29/92; H01L 21/8234

(52) U.S. Cl. 257/312; 438/379; 257/E29.342; 257/E21.616

(57) ABSTRACT

A variable capacitance device including a plurality of FETs, the sources and drains of each FET being coupled to a first terminal, the gates of each FET being coupled to a second terminal, the capacitance of said device between said first and second terminals varying as a function of the voltage across said terminals, the device further including a biasing providing a respective backgate bias voltage to each the FETs setting a respective gate threshold voltage thereof. The aggregate V-C characteristic can be tuned as desired, either at design time or dynamically. The greater the number of FETs forming the varactor, the greater the number of possible Vt values that can be individually set, so that arbitrary V-C characteristics can be more closely approximated.

### FIELD OF THE INVENTION

The present invention relates to solid state devices, and more particularly, to a tunable capacitance device or varactor.

### BACKGROUND AND RELATED ART

Varactors, or voltage-controlled capacitors, are important devices in integrated circuits which allow the construction of circuits such as voltage-controlled oscillators (VCOs) and to other circuits requiring a tunable capacitance.

FIG. 1 illustrates a CMOS varactor as known in the art. As shown, a conventional varactor includes a CMOS gate, which may operate in an inversion mode (IMOS) or in an accumulation mode (AMOS). The device consists of a source 111, a drain 114, a gate 112 separated from the channel region between the source and the drain, preferably by an insulating oxide layer 113. The gate 112 is coupled to a first terminal T1 while the source 111 and drain 114 are electronically connected to a second terminal t2.

FIG. 2 shows the conventional varactor symbol with a corresponding configuration as concerns terminals T1 and t2, whereby in an inversion mode, the device exhibits a high capacitance across the terminals T1 t2 when a positive voltage is applied to the gate, which attracts electrons under the gate, forming an inversion region referred to as the channel. In an accumulation mode, varactors have n+ diffusions in an n-well, rather than in a p-type region. The capacitance across terminals T1 and t2 is high when a positive voltage is applied to the gate, attracting electrons under the gate and forming an accumulation region. AMOS varactors generally offer higher Q, since there are fewer parasitic junctions and paths to ground.

The crossover between high and low capacitance occurs around the threshold voltage of the FET device, and is relatively linear, if abrupt, in this region.

The desirable properties are a large range of capacitance tuning, for example, a value Cmax/Cmin greater than 3 is desirable, and a gradual change of capacitance with voltage. MOS capacitors in accumulation mode are generally used because they can be implemented without additional masks. However, they tend to have abrupt C-V curves. P-N junctions exhibit gradual C-V curves but tend to have a value of Cmax/Cmin of around 1.5.

By adding a custom doping profile under a p-n junction one can obtain a gradual C-V curve inherent to p-n junctions with a higher capacitance ratio. However, it comes at a cost of an additional mask and would be impossible to implement in a fully-depleted SOI.

Moreover, the prior art describes double-gate structures allowing independent switching of the gates or dynamic adjusting of the threshold voltage.

### SUMMARY

According to an embodiment of the present invention, there is provided a variable capacitance device (also referred to varactor) and tuned circuit.

In one aspect, in one embodiment, varactors can be configured in an array of the backgate varactors capable of achieving a gradual C-V curve, i.e., the sum of each element of the array having a shifted turn-on voltage.

In one aspect, an embodiment of the invention takes advantage of the fact that V_{T} is controlled not by doping but by the backgate voltage. It is relatively easy to change the V_{T} of varactors on bulk silicon by changing the doping under the gate.

In one aspect, an embodiment of the invention provides a variable capacitance device including a plurality of FETs, the source and drain of each FET being coupled to a first terminal, the gates of each FET being coupled to a second terminal, such that the capacitance of the device between the first and second terminals varies as a function of the voltage across the terminals, the device including a biasing circuit providing a respective backgate bias voltage to each of the FETs to set a respective gate threshold voltage thereof.

In one aspect, an embodiment of the invention provides a method of forming a varactor device on a substrate including: forming a plurality of FETs, each of the FET having a source, a drain and at least one gate, each of the FETs drain and source being coupled to a first terminal and one or more gates of each of the FETs coupled to a second terminal; varying the capacitance of the device as a function of the voltage across the first and second terminals; and applying a bias providing respectively a backgate bias voltage to each the FET to set a respective gate threshold voltage thereof.

Further advantages and aspects of the present invention will become clear to the skilled person upon examination of the drawings and detailed description.

### BRIEF DESCRIPTION OF THE DRAWINGS

The invention itself, however, as well as a preferred mode of use, further aspects and advantages thereof, will best be understood by reference to the following detailed description of illustrative embodiments when read in conjunction with the accompanying drawings in which:

FIG. 1 illustrates a prior art CMOS varactor;

FIG. 2 shows the conventional varactor symbol with a corresponding configuration as concerns terminals T1 and T2;

FIG. 3 shows in cross section a varactor, in accordance with an embodiment of the invention;

FIGS. 4a, 4b, 4c and 4d show the respective C-V characteristics of each of the four FETs individually;

FIG. 5 shows the resulting aggregate C-VC-V characteristic of the array, combining the four characteristics as shown in FIG. 4;

FIGS. 6a, 6b, 6c and 6d show the respective C-V characteristics of each of the four FETs individually as describe above;

FIG. 7 shows the resulting aggregate C-V characteristic of the array, combining the four characteristics described with regard to FIG. 6; and

FIG. 8 shows an arbitrary C-V response in accordance with an embodiment of the present invention.

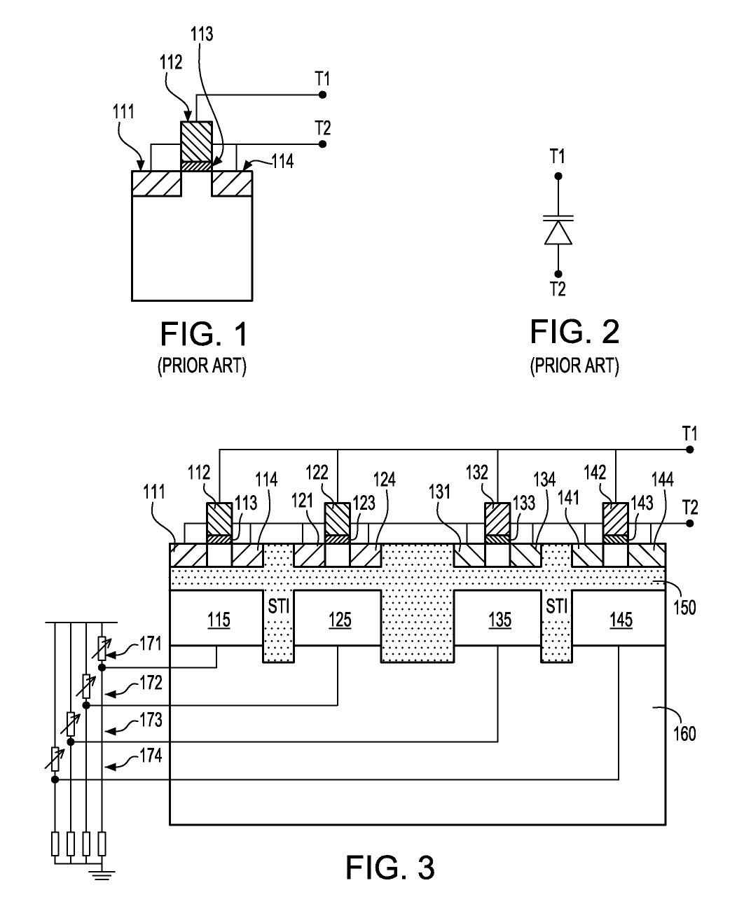

### DETAILED DESCRIPTION OF PREFERRED EMBODIMENTS

Embodiments of the present invention will now be described by way of example with reference to the accompanying drawings in which like references denote similar elements, and in which:

It is observed that by including a backgate, or biased groundplane, for example in a fully depleted silicon-on-insulator (FDSOI) technology, one can tune the threshold voltage of an individual FET. This principle may be advantageously applied to varactors, which may then be used forming an array to achieve the high Cmax/Cmin inherent to MOS capacitors along with a gradual C-V curve which is the sum of each element of the array having a shifted turn-on voltage.

FIG. 3 shows a side cross sectional schematic of a varactor according to an embodiment of the invention. As shown, there is provided a substrate 160 upon which are preferably formed four double gate FETs. Each FET is provided with a source 111, 121, 131, 141, a gate 112, 122, 132, 142, an insulating layer 113, 123, 133, 143, a drain 114, 124, 134, 144 and a backgate 115, 125, 135, 145. The FETs are separated from one another by a series of shallow trench isolation (STI) trenches. The channel region of each FET is separated from its corresponding backgate by an insulating plane 150 intersecting the trenches. A tuning voltage is applied respectively to the backgate 115, 125, 135, 145 of each FET. Each respective tuning voltage is preferably determined as described hereinafter, to provide the desired V/C characteristic to the varactor device as a whole. The sources 111, 121, 131, 141 and drains 114, 124, 134, 144 are coupled to terminal T1 and the gates 112, 122, 132, 142 are coupled to terminal t2. The generation of the respective tuning voltages is represented schematically by a set of biasing circuits in the form of voltage divider 171, 172, 173, 174.

In accordance with an embodiment, a variable capacitance device includes a plurality of FETs, the sources and drains of the FETs being coupled to a first terminal, and the gates of the FETs being coupled to a second terminal, such that the capacitance of the device between the first and second terminals varies as a function of the voltage across the terminals T1 and T2. The device further includes a biasing circuit providing a respective backgate bias voltage to each of the FETs, setting a respective gate threshold voltage thereof.

These aforementioned FETs can be n-type or p-type. Likewise, the backgates can be of n-type or p-type.

By applying separate respective tuning voltages the backgate of each FET in the array, the threshold voltage V_{T} of each FET can be individually tuned. The number of FETs in the array, and the V_{T} values set for each FET determines the shape of the overall C-V characteristic for the varactor device as a whole, across terminals T1 and T2.

Thus, the biasing circuit provides a backgate bias voltage to each the FET so as to set the gate threshold voltage of each FET to a different value.

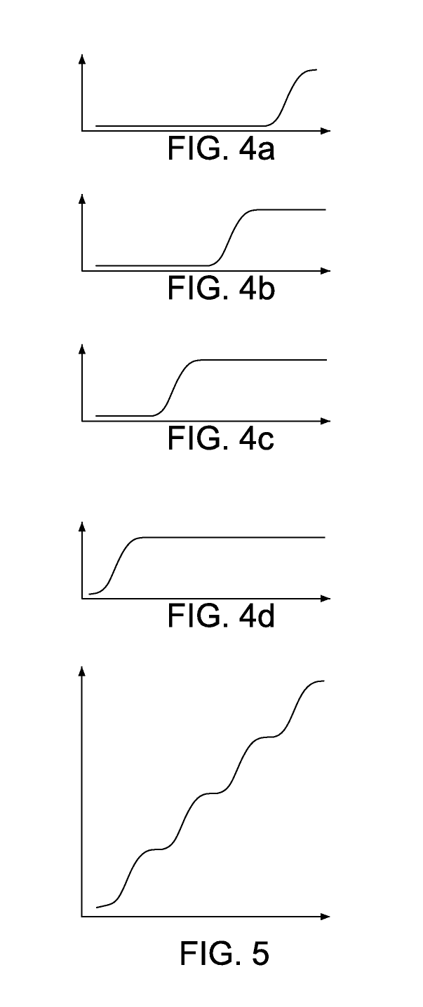

FIGS. 4a, 4b, 4c and 4d show the respective C-V characteristics of each of the four FETs individually as describe above. As shown, the V_{T} values of each FET are selected to stagger the voltage at which the respective FETs switches on, such that when the control voltage V rises, the V_{T} values of the respective FETs are reached one after another. Since the individual FETs are coupled as varactors in parallel, the capacitances of the individual devices are added to give the capacitance of the array as a whole.

FIG. 5 shows the resulting aggregate C-V characteristic of the array, combining the four characteristics described with reference to FIG. 4. As shown, four staggered curves are added to approximate a gradual change in capacitance over a large range. It will be appreciated that this range being a function of the total number of V_{T}s in the array, the number of V_{T}s may not exceed the number of FETs. In such an instance, when it is desired to minimize this number, the count of V_{T}s may simply be increased as required. Furthermore, the V_{T} values can be distributed to obtain the desired aggregate C-V relationship.

According to one embodiment, the gate threshold voltage of each FET is advantageously set to a different value at regular intervals in order for the capacitance-voltage characteristic approximate the linear capacitance-voltage characteristic.

A large substantially linear range of this kind is useful in many applications, for example, in voltage controlled oscillators (VCOs).

The effect of setting the V_{T} of all the FETs forming the array to the same value may also be considered.

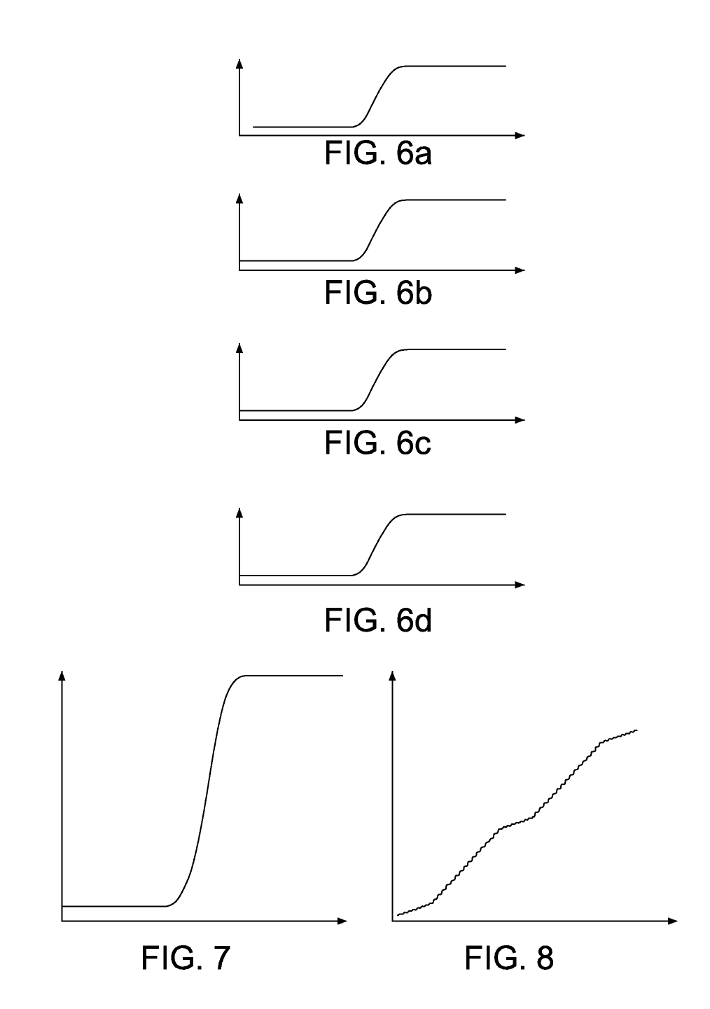

FIGS. 6a, 6b, 6c and 6d show respective C-V characteristics of each of the four FETs individually described above. As shown, the V_{T} values of each FET are set to the same value.

Since the individual FETs are coupled as varactors in parallel, the capacitances of the individual devices are added to provide the overall total capacitance of the entire array.

FIG. 7 shows the resulting aggregate C-V characteristic of the array, combining the four characteristics described with reference to FIG. 6. As shown, the four curves are added, giving an abrupt characteristic that may be expected of a single FET varactor having an area equivalent to the four devices of the present embodiment. Although this in itself may be of little use, it is worth noting that the aforementioned curve can be obtained merely by changing the respective tuning voltage applied to the backgate of each FET.

On this basis, a system integrating the array varactor may switch between the characteristics of FIG. 5 and FIG. 7 at will. The ability to oscillate between different C-VC-V characteristics in the described manner may be of use in many applications. By way of example, one may envisage a tuned circuit, e.g., a radio receiver, switching between the steep characteristic of FIG. 7 in a coarse tuning mode, and the gradual characteristic of FIG. 5 in a fine tuning mode.

In summary, in one embodiment, a tuned circuit is provided that includes a device in which the gate threshold voltage of each FET is set to a different value at regular intervals such that the capacitance-voltage characteristic provides a frequency response giving finer tuning selectivity within a defined frequency range, and coarser tuning selectivity in adjacent frequency ranges.

In addition, as observed above, the degree to which the curve can be optimized depends to a certain extent on the number of FETs in the array. According to one embodiment, the array may contain a large number of FETs. In such an instance, it becomes possible not only to better approximate a linear C-V characteristic, but also to program an arbitrary characteristic within the physical limitations of the devices used.

FIG. 8 shows an arbitrary C-V response in accordance with an embodiment of the invention. As illustrated, the characteristic incorporates three regions having a relatively flat characteristic, and two intervening sections with comparatively steep characteristics. The example of FIG. 8 indicates that the array varactor described herein may be advantageously used in tuned circuits, wherein certain frequency bands are known to be heavily used, leaving others to be relatively unused. By setting an overall characteristic as shown in FIG. 8, the flat regions correspond to the heavily used frequency bands, ensuring that tuning is most sensitive where sensitivity is most needed.

Still further, the readily tunable nature of the array varactor described herein shows that the characteristic may be dynamically reprogrammed as a result of changing conditions. To this end, there may be provided with a process adapted to dynamically control the characteristic.

Thus the biasing circuit is adapted to provide a variable backgate bias voltage to each FET, enabling a dynamic definition of the capacitance-voltage characteristic.

Although in the preceding discussion it has been assumed that the FET devices of which the varactor array preferably have the same composition. It will be appreciated that there are many physical factors which may also be tuned to emphasize or optimize the effects of applying a separate respective tuning voltage of the backgate of each FET in the array as previously described. By way of example, different types or levels of doping may be applied to the source and or drain regions from one FET to the next, or the dimensions of the devices may be varied, e.g., to set different channel lengths from one FET to the next. Since these factors all have an effect on the threshold voltage, certain FETs in the array may be designed to be physically preset at a higher or lower V_{T}, naturally falling into a particular position in the order of FETs when they are set at staggered V_{T} values. Different FETs may also be designed with a lesser or greater capacitance relative to other FETs in the array. On this basis, FETs having different capacitance values may be set to different positions in the V_{T} hierarchy depending on the extent of the effect on the final resulting characteristic. Thus, the level or type of doping of the FET channels or backgates may be determined heterogeneously so as to set the gate threshold voltage of each FET to a different value.

According to one embodiment, connections between the FETs may be switched, in order that the composition of the array from a functional point of view may be modified as required. This approach may be particularly advantageous where a number of devices are provided with different physical characteristics, whereby devices best adapted to the desired overall characteristic are selected. Appropriate processing circuits may be provided to control such switching operations.

Certain embodiments have been described with reference to applications in the field of tuned circuits, and in particular for radio receivers. It will be appreciated that the array varactor as described finds a use in many fields where a variable capacitance device may be required, such as, for example adjustable filters or oscillator circuits.

The forgoing embodiments have been described in terms of FDSOI technology. It will be appreciated that the same effect could be obtained by means of other technologies, for example on a “bulk” silicon substrate using implanted well-isolated varactors, notwithstanding the fact that inversion-mode varactors are of lower performance than the accumulation-mode varactors typically used on bulk.

According to one embodiment, the backgate material of one or more of the FETs may not be of a doped semiconductor material as discussed above, but rather be made of metal, wherein the metal is selected as having a particular work function, in view of the fact that the gate work function also affects the V_{T}. Thus, the FETs may include gates of different work functions to be used as a backgate.

The aggregate V-C characteristic can be tuned as desired, either at design time or dynamically. The greater the number of FETs forming the varactor, the greater the number of possible Vt values that can be individually set, allowing arbitrary V-C characteristics to be more closely approximated.

The invention can take the form of an entirely hardware embodiment, or an embodiment containing both hardware and software elements, in particular with regard to the dynamic control of C-V characteristics by processor means as described above. In one embodiment, part of the invention can be implemented in software, which includes but is not limited to firmware, resident software, microcode, and the like.

Furthermore, the invention can take the form of a computer program product accessible from a computer-usable or computer-readable medium providing program code for use by or in connection with a computer or any instruction execution system. For the illustrative purposes, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk a read only memory (CD-ROM), compact disk read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

While the present invention has been particularly shown and described with respect to preferred embodiments thereof, it will be understood by those skilled in the art that the foregoing and other changes in forms and details may be made without departing from the spirit and scope of the invention. It is therefore intended that the present invention not be limited to the exact forms and details described and illustrated but fall within the scope of the appended claims.

1. A variable capacitance device comprising one or more FETs having a source, a drain and at least one gate, each of the FETs source and drain coupled to a first terminal and the FET at least one gate coupled to a second terminal, the capacitance of the device between the first and second terminals varying as a function of a voltage across the terminals, the device further including a bias voltage providing a backgate bias voltage to each the FETs, respectively setting a gate threshold voltage thereof.

2. The variable capacitance device as recited in claim 1 wherein said bias provides a respective backgate bias voltage to each said FETs, setting said gate threshold voltage of each of said FETs to a different value.

3. The variable capacitance device as recited in claim 2 wherein said gate threshold voltage of each of said FETs is set to a different value at regular intervals such that capacitance-voltage characteristics approximate a linear capacitance-voltage characteristic.

4. The variable capacitance device as recited in claim 3 wherein said bias further provides a variable backgate bias voltage to each said FETs enabling a dynamic definition of said capacitance-voltage characteristic.

5. The variable capacitance device as recited in claim 2 wherein a level or type of doping of FET channels or backgates are determined heterogeneously for setting said gate threshold voltage of each of said FETs at a different value.

6. The variable capacitance device as recited in claim 2 further comprising an array of backgate devices that achieving a gradual C-V curve, wherein a sum of each element of the array are provided with a shifted turn-on voltage.

7. The variable capacitance device as recited in claim 1 wherein said FETs operate in an inversion mode.

8. The variable capacitance device as recited in claim 1 wherein said FETs are implemented using FDSOI technology.

9. The variable capacitance device as recited in claim 1, wherein said FETs further comprise gates having different work function used as a backgate.

10. The variable capacitance device as recited in claim 2, further comprising a tuned circuit wherein the gate threshold voltage of each of said FETs is set to a different value at regular intervals such that the capacitance-voltage characteristic provides a frequency response giving a finer tuning selectivity within a defined frequency range, and a coarser tuning selectivity in adjacent frequency ranges.

11. A method of forming varactor devices on a substrate comprising:
forming on said substrate a plurality of FETs, each of said FET having a source, a drain and at least one gate, each of said FETs drain and source being coupled to a first terminal and said at least one gate of each of said FETs coupled to a second terminal;
varying a capacitance of said devices as a function of a voltage across said first and second terminals; and
applying a bias voltage respectively providing a backgate bias to each said FETs setting a respective gate threshold voltage thereof.

12. The method as recited in claim 11, wherein applying said bias provides a respective backgate bias voltage to each said FETs, setting said gate threshold voltage of each of said FETs to a different value.

13. The method as recited in claim 12, wherein setting said gate threshold voltage of each of said FETs at a different value at regular intervals enables capacitance-voltage characteristics approximate a linear capacitance-voltage characteristic.
